(19) United States
(12) Patent Application Publication
(10) Pub. No.: US 2026/0195259 A1
(43) Pub. Date: Jul. 9, 2026

(54) MITIGATION FOR CAPACITIVE COUPLING IN ELECTRICAL PATHWAYS IN NON-VOLATILE MEMORY DIES

(71) Applicant: Sandisk Technologies, Inc., Milpitas, CA (US)

(72) Inventor: Jayavel Pachamuthu, San Jose, CA (US)

(73) Assignee: Sandisk Technologies, Inc., Milpitas, CA (US)

(21) Appl. No.: 19/014,638

(22) Filed: Jan. 9, 2025

(51) Int. Cl. G06F 12/02; H01L 25/00; H01L 25/16; H10B 80/00

(52) U.S. Cl. CPC G06F 12/0246; H10B 80/00; H10W 90/00; H10W 90/24; H10W 90/297

(57) ABSTRACT

Technology for mitigating capacitive coupling effects associated with electrical pathways that extend through a stack of multiple dies. The multiple dies include memory structures having non-volatile memory cells such as NAND. The multiple dies may also include control circuitry that performs die level control of the non-volatile memory cells. This control circuitry may be formed on a semiconductor substrate such as a crystalline silicon substrate. The electrical pathways may extend through a stack of dies. The electrical pathways may include through silicon vias (TSVs) that extend through the crystalline semiconductor substrate in which the control circuitry is formed.

### BACKGROUND

The present disclosure relates to non-volatile storage.

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. Non-volatile memory allows information to be stored and retained even when the non-volatile memory is not connected to a source of power (e.g., a battery).

A memory structure in the memory system typically contains many memory cells and various control lines. The memory structure may be three-dimensional (3D). One type of 3D memory structure has non-volatile memory cells arranged as vertical NAND strings (where “vertical” is defined with respect to a substrate on which the 3D memory structure is formed).

A memory system may have control circuits to operate the memory structure (e.g., to perform memory access operations including read, write and erase operations). Some or all control circuits may be located on a separate die (e.g., a memory structure may be located on one or more memory dies and control circuits may be located on one or more additional dies). In some cases multiple dies may be combined (e.g., stacked) to form a larger assembly. Electrical pathways may be used to connect different dies in such an assembly. Capacitive coupling between such electrical pathways may interfere with signal integrity. Degraded signal integrity could result in data errors. Capacitive coupling between such electrical pathways can also increase RC delay, thereby impairing signal transmission speed.

### BRIEF DESCRIPTION OF THE DRAWINGS

Like-numbered elements refer to common components in the different figures.

FIG. 1 is a block diagram depicting one embodiment of a storage system.

FIG. 2A is a block diagram of one embodiment of a memory die.

FIG. 2B is a block diagram of one embodiment of an integrated memory assembly.

FIGS. 3A and 3B depict different embodiments of integrated memory assemblies.

FIG. 3C illustrates a stacked memory assembly with Deep Trench Contacts (DTCs).

FIG. 4 is a perspective view of a portion of one example embodiment of a monolithic three dimensional memory structure.

FIG. 4A is a block diagram of one embodiment of a memory structure having two planes.

FIG. 5 shows an example of an integrated memory assembly in cross section.

FIG. 6A shows an embodiment of a mirrored die pair formed of two integrated memory assemblies.

FIG. 6B is a simplified diagram of a vertical stack of an embodiment of a mirror dies formed from two integrated memory assemblies.

FIG. 7 shows a portion of a mirrored die pair in cross section.

FIG. 8A show an example of a stack of mirrored die pairs.

FIG. 8B is a simplified diagram of top view of an embodiment of mirror die pair 800_1 in FIG. 8A.

FIG. 8C shows an example of Deep Trench Contacts (DTCs) in a stack of mirrored die pairs.

FIG. 9A is a cross-sectional view of a portion of two DTCs in a substrate.

FIG. 9B is a cross-section along line 9B-9B in FIG. 9A.

FIG. 9C is a cross-section along line 9C-9C in FIG. 9A.

FIGS. 10A and 10B show an embodiment in which the DTCs have a low permittivity dielectric without an air gap.

FIG. 11A is a cross-sectional view of a portion of two DTCs in a substrate.

FIG. 11B is a cross-section along line 11B-11B in FIG. 11A.

FIG. 12 is a cross-sectional diagram of a portion of two DTCs in silicon substrates of two control dies bonded together.

FIG. 13 is a flowchart of one embodiment of a process of fabricating a DTC/TSV in a substrate.

FIGS. 14A-14P shows results during an embodiment of the fabrication process of FIG. 13.

### DETAILED DESCRIPTION

Technology is disclosed for mitigating capacitive coupling effects associated with electrical pathways that extend through a stack of multiple dies. In one embodiment, the multiple dies include memory structures having non-volatile memory cells such as NAND. The multiple dies may also include control circuitry that performs die level control of the non-volatile memory cells. This control circuitry may be formed on a semiconductor substrate such as a crystalline silicon substrate. The electrical pathways may include through silicon vias (TSVs) that extend through the crystalline semiconductor substrates in which the control circuitry is formed. The electrical pathways may also pass through silicon dioxide or the like above a crystalline semiconductor substrate. In an embodiment, the electrical pathways extend through the stack of dies and are coupled to the control circuitry to permit off-die communication with the control circuitry. Off die communication means communication with a sender or receiver that is external to the die on which the control circuitry resides. The multiple dies may be connected to a memory controller or the like, which may issue commands to read and/or write the non-volatile memory cells. The electrical pathways may be used by the memory controller to transfer data, memory cell addresses, or other signals. Note that herein examples in which the semiconductor substrate is silicon will be discussed. Other examples for the semiconductor substrate include, but are not limited to, Germanium, Gallium Arsenide, Indium Phosphide, and Cadmium Selenium. More generally, the semiconductor substrate could be a Group-IV semiconductor, a Group III-V semiconductor, or a Group II-VI semiconductor.

Capacitive coupling between neighboring electrical pathways could compromise signal integrity of the signals transmitted on the electrical pathways. In an embodiment, the electrical pathways are surrounded by a low permittivity dielectric. Herein, a low permittivity dielectric is defined relative to silicon dioxide (SiO₂). A low permittivity dielectric has a lower dielectric permittivity than the dielectric permittivity of silicon dioxide (SiO₂). A low permittivity dielectric material may also be referred to as a low dielectric constant (low-k) material. In one embodiment, the low permittivity dielectric is air (e.g., air gap). However, the low permittivity dielectric could be a solid material. The low permittivity dielectric mitigates capacitive coupling issues and therefore improves signal integrity. Bit error rates for data storage may be reduced by improving the signal integrity. Also, the low permittivity dielectric helps to reduce RC delay, thereby improving signal transmission speed. Furthermore, reducing the capacitive coupling allows the possibility for reducing the critical dimension of conductive columns used for the electrical pathways.

Although not a requirement, the stack of multiple dies could be used for artificial intelligence (AI) compute applications. AI compute applications require energy efficient, high-performance, low-latency, and high-bandwidth for data caching, writing, intense reading and for inferences. The capacitive coupling between the neighboring electrical pathways could significantly impair AI compute applications. The low permittivity dielectric that surrounds the electrical pathways reduces interference effects to thereby improves inference for AI compute applications. Also, AI compute applications typically require very high bandwidth transfer of AI model parameters (e.g., weights) that may be stored in memory such as NAND. Mitigating capacitive coupling with the low permittivity dielectric increases bandwidth of data, such as AI model parameters, transferred from the memory cells.

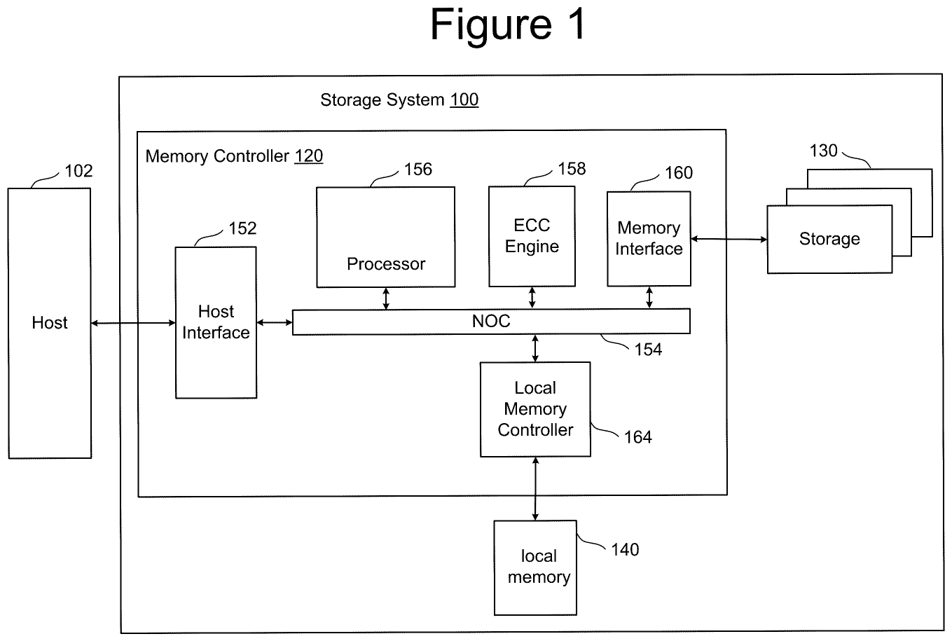

FIG. 1 is a block diagram of one embodiment of a storage system 100 that implements the technology described herein. In one embodiment, storage system 100 is a solid state drive (“SSD”). Storage system 100 can also be a memory card, USB drive or other type of storage system. The proposed technology is not limited to any one type of storage system. Storage system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 120 (or storage controller) connected to non-volatile storage 130 and local high speed memory 140 (e.g., DRAM, SRAM, MRAM). Local memory 140 is non-transitory memory, which may include volatile memory or non-volatile memory. Local high speed memory 140 is used by memory controller 120 to perform certain operations. For example, local high speed memory 140 may store logical to physical address translation tables (“L2P tables”).

Memory controller 120 comprises a host interface 152 that is connected to and in communication with host 102. In one embodiment, host interface 152 implements an NVM Express (NVMe) over PCI Express (PCIe). Other interfaces can also be used, such as SCSI, SATA, etc. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus. Connected to and in communication with NOC 154 is processor 156, ECC engine 158, memory interface 160, and local memory controller 164. Local memory controller 164 is used to operate and communicate with local high speed memory 140 (e.g., DRAM, SRAM, MRAM).

ECC engine 158 performs error correction services. For example, ECC engine 158 performs data encoding and decoding. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156.

Processor 156 performs the various controller memory operations, such as programming, erasing, reading, and memory management processes. In one embodiment, processor 156 is programmed by firmware. In other embodiments, processor 156 is a custom and dedicated hardware circuit without any software. Processor 156 also implements a translation module, as a software/firmware process or as a dedicated hardware circuit. In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To implement this system, memory controller 120 (e.g., the translation module) performs address translation between the logical addresses used by the host and the physical addresses used by the memory die. One example implementation is to maintain tables (i.e., the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 140 cannot hold all of the L2P tables. In such a case, the entire set of L2P tables are stored in a storage 130 and a subset of the L2P tables are cached (L2P cache) in the local high speed memory 140.

Memory interface 160 communicates with non-volatile storage 130. In one embodiment, memory interface provides a Toggle Mode interface. Other interfaces can also be used. In some example implementations, memory interface 160 (or another portion of controller 120) implements a scheduler and buffer for transmitting data to and receiving data from one or more memory die.

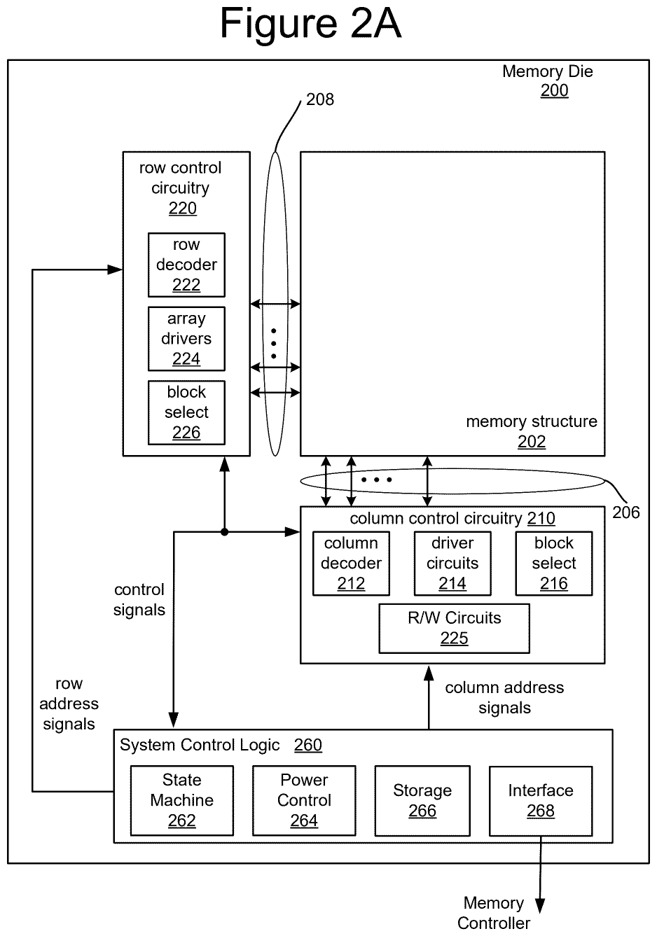

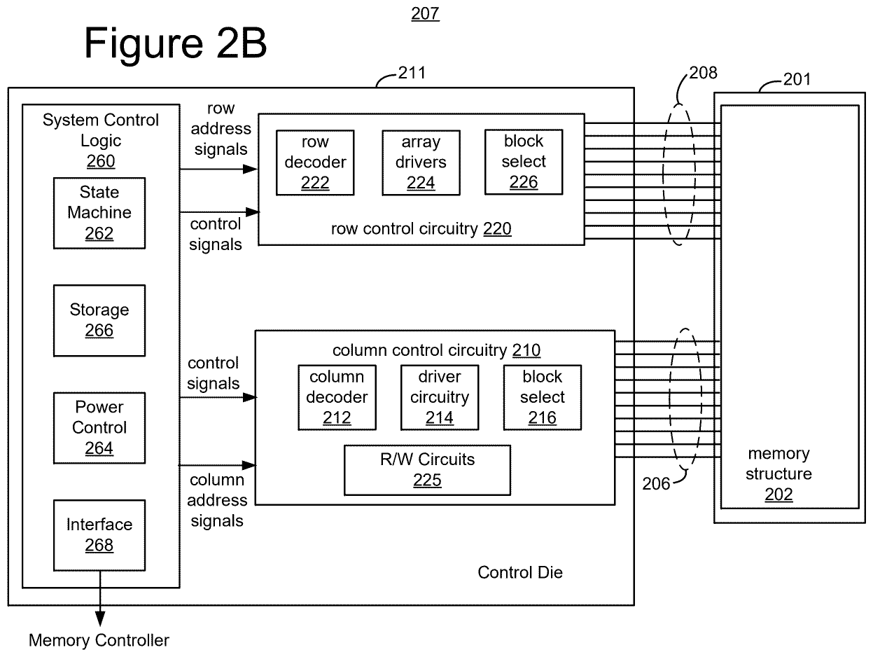

In one embodiment, non-volatile storage 130 comprises one or more memory dies. FIG. 2A is a functional block diagram of one embodiment of a memory die 200 that comprises non-volatile storage 130. Each of the one or more memory dies of non-volatile storage 130 can be implemented as memory die 200 of FIG. 2A. The components depicted in FIG. 2A are electrical circuits. Memory die 200 includes a memory structure 202 (e.g., memory array) that can comprise non-volatile memory cells (also referred to as non-volatile storage cells), as described in more detail below. The array terminal lines of memory structure 202 include the various layer(s) of word lines organized as rows, and the various layer(s) of bit lines organized as columns. However, other orientations can also be implemented. Memory die 200 includes row control circuitry 220, whose outputs are connected to respective word lines of the memory structure 202. Row control circuitry 220 receives a group of M row address signals and one or more various control signals from System Control Logic circuit 260, and typically may include such circuits as row decoders 222, array drivers 224, and block select circuitry 226 for both reading and writing (programming) operations. Row control circuitry 220 may also include read/write circuitry. Memory die 200 also includes column control circuitry 210 including read/write circuits 225. The read/write circuits 225 may contain sense amplifiers and data latches. The sense amplifier(s) input/outputs are connected to respective bit lines of the memory structure 202. Although only single block is shown for structure 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select circuitry 216, as well as read/write circuitry, and I/O multiplexers. The system control logic 260, column control circuitry 210, and/or row control circuity 220 are configured to control memory operations such as open block reads at the die level.

System control logic 260 receives data and commands from memory controller 120 and provides output data and status to the host. In some embodiments, the system control logic 260 (which comprises one or more electrical circuits) includes state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 260 can also include a power control module 264 that controls the power and voltages supplied to the rows and columns of the memory structure 202 during memory operations. System control logic 260 includes storage 266 (e.g., RAM, registers, latches, etc.), which may be used to store parameters for operating the memory structure 202.

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used.

In some embodiments, all the elements of memory die 200, including the system control logic 260, can be formed as part of a single die. In other embodiments, some or all of the system control logic 260 can be formed on a different die than the die that contains the memory structure 202.

In one embodiment, memory structure 202 comprises a three-dimensional memory array of non-volatile memory cells in which multiple memory levels are formed above a single substrate, such as a wafer. The memory structure may comprise any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory structure 202 comprises a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM (ferroelectric random access memories), phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created.

Phase change memory (PCM) utilizes the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or other wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) memory structure 202 and (2) peripheral circuitry, which includes all of the other components depicted in FIG. 2A. An important characteristic of a memory circuit is its capacity, which can be increased by increasing the area of the memory die of storage system 100 that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the storage system 100 is the amount of area to devote to the memory structure 202 and the amount of area to devote to the peripheral circuitry.

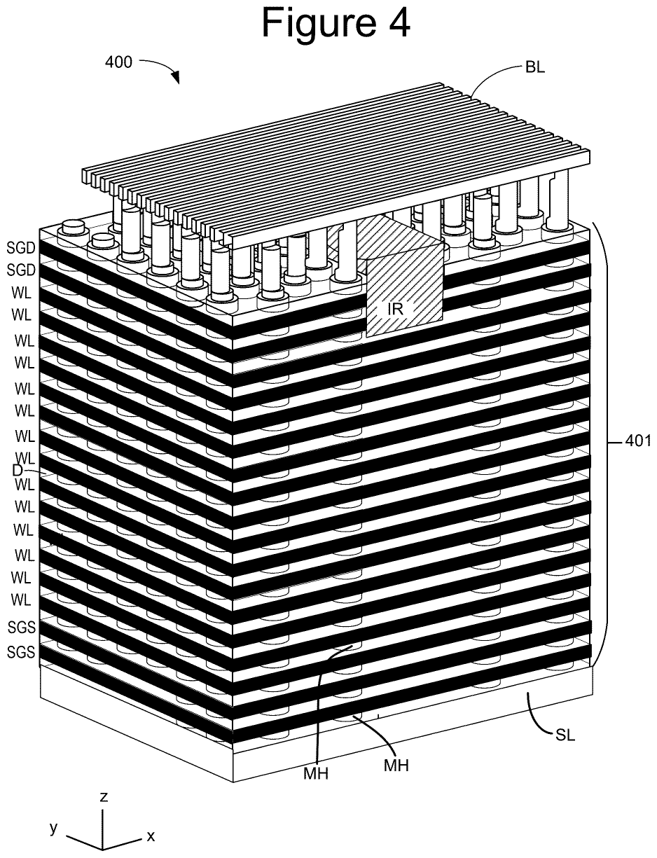

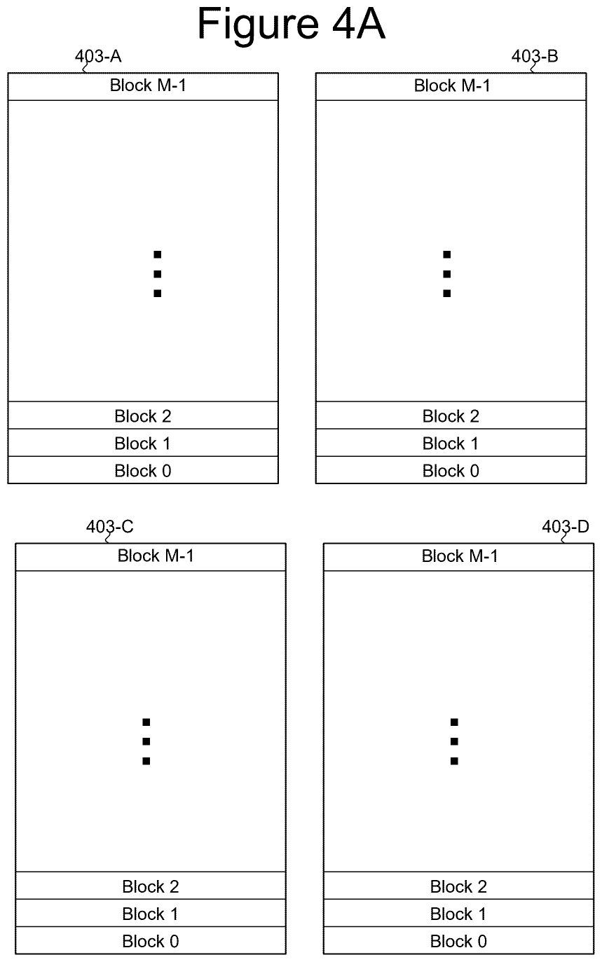

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies. Three-dimensional NAND structures (see, for example, FIG. 4) in particular may benefit from specialized processing operations.

To improve upon these limitations, embodiments described below can separate the elements of FIG. 2A onto separately formed dies that are then bonded together. More specifically, the memory structure 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory die and one control die, other embodiments can use more dies, such as two memory dies and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 207. One or more integrated memory assemblies 207 may be used to implement the non-volatile storage 130 of storage system 100. The integrated memory assembly 207 includes two types of semiconductor dies (or more succinctly, “die”). Memory structure die 201 includes memory structure 202. Memory structure 202 includes non-volatile memory cells. Control die 211 includes control circuitry 260, 210, and 220 (as described above). In some embodiments, control die 211 is configured to connect to the memory structure 202 in the memory structure die 201. In some embodiments, the memory structure die 201 and the control die 211 are bonded together.

FIG. 2B shows an example of the peripheral circuitry, including control circuits, formed in a peripheral circuit or control die 211 coupled to memory structure 202 formed in memory structure die 201. Common components are labelled similarly to FIG. 2A. System control logic 260, row control circuitry 220, and column control circuitry 210 are located in control die 211. In some embodiments, all or a portion of the column control circuitry 210 and all or a portion of the row control circuitry 220 are located on the memory structure die 201. In some embodiments, some of the circuitry in the system control logic 260 is located on the on the memory structure die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate controller 120 may also be used to fabricate system control logic 260, row control circuitry 220, and column control circuitry 210). Thus, while moving such circuits from a die such as memory structure die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2B shows column control circuitry 210 including read/write circuits 225 on the control die 211 coupled to memory structure 202 on the memory structure die 201 through electrical paths 206. For example, electrical paths 206 may provide electrical connection between column decoder 212, driver circuitry 214, and block select 216 and bit lines of memory structure 202. Electrical paths may extend from column control circuitry 210 in control die 211 through pads on control die 211 that are bonded to corresponding pads of the memory structure die 201, which are connected to bit lines of memory structure 202. Each bit line of memory structure 202 may have a corresponding electrical path in electrical paths 206, including a pair of bond pads, which connects to column control circuitry 210. Similarly, row control circuitry 220, including row decoder 222, array drivers 224, and block select 226 are coupled to memory structure 202 through electrical paths 208. Each electrical path 208 may correspond to a word line, dummy word line, or select gate line. Additional electrical paths may also be provided between control die 211 and memory structure die 201.

For purposes of this document, the phrases “a control circuit” or “one or more control circuits” can include any one of or any combination of all or a portion of system control logic 260, all or a portion of row control circuitry 220, all or a portion of column control circuitry 210, read/write circuits 225, sense amps, a microcontroller, a microprocessor, and/or other similar functioned circuits. A control circuit can include hardware only or a combination of hardware and software (including firmware). For example, a controller programmed by firmware to perform the functions described herein is one example of a control circuit. A control circuit can include a processor, FPGA, ASIC, integrated circuit, or other type of circuit.

For purposes of this document, the term “apparatus” can include, but is not limited to, one or more of, storage system 100, storage 130, a stack that includes memory dies 200, a stack that includes integrated memory assemblies 207, and/or a stack that includes control dies 211.

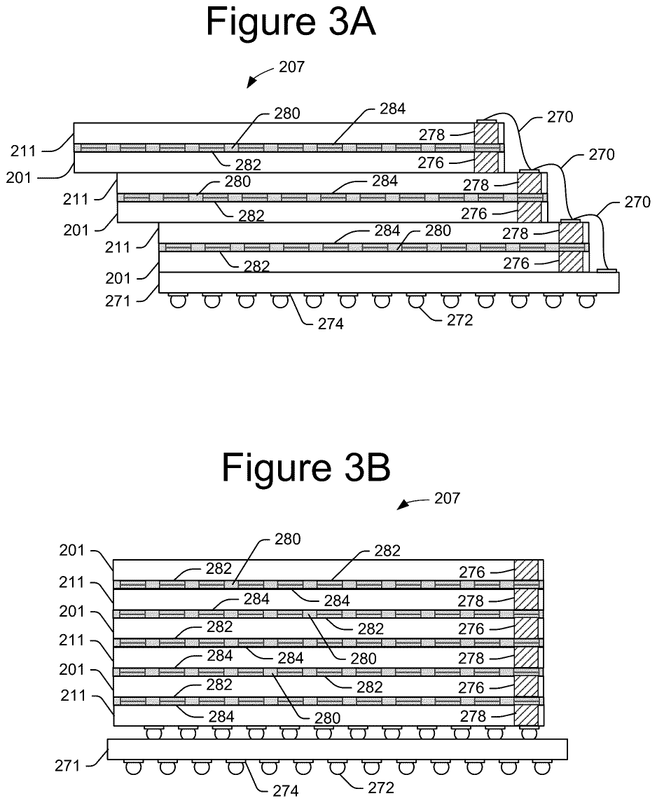

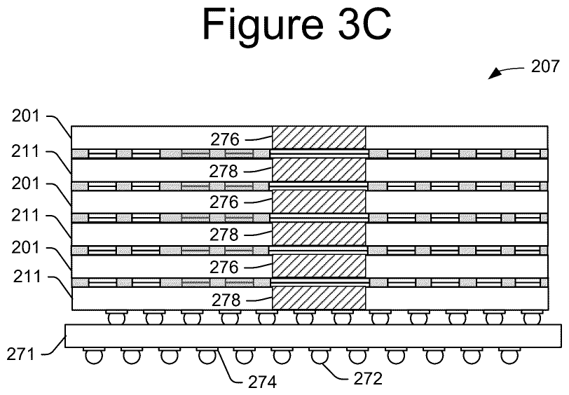

In some embodiments, there is more than one control die 211 and more than one memory structure die 201 in an integrated memory assembly 207. In some embodiments, the integrated memory assembly 207 includes a stack of multiple control dies 211 and multiple memory structure dies 201. FIG. 3A depicts a side view of an embodiment of an integrated memory assembly 207 stacked on a substrate 271 (e.g., a stack comprising control die 211 and memory structure die). The integrated memory assembly 207 has three control dies 211 and three memory structure dies 201. In some embodiments, there are more than three memory structure dies 201 and more than three control dies 211. In FIG. 3A there are an equal number of memory structure dies 201 and control dies 211; however, in one embodiment, there are more memory structure dies 201 than control dies 211. For example, one control die 211 could control multiple memory structure dies 201.

Each control die 211 is affixed (e.g., bonded) to at least one of the memory structure die 201. Some of the bond pads 282/284 are depicted. There may be many more bond pads. A space between two die 201, 211 that are bonded together is filled with a solid layer 280, which may be formed from epoxy or other resin or polymer or dielectric material such as silicon oxide, silicon nitride, or other similar dielectric materials. Other similar materials may be used. This solid layer 280 protects the electrical connections between the die 201, 211, and further secures the die together. Various materials may be used as solid layer 280.

The integrated memory assembly 207 may for example be stacked with a stepped offset, leaving the bond pads at each level uncovered and accessible from above. Wire bonds 270 connected to the bond pads connect the control die 211 to the substrate 271. A number of such wire bonds may be formed across the width of each control die 211 (i.e., into the page of FIG. 3A).

A memory die through silicon via (TSV) 276 may be used to route signals through a memory structure die 201. A control die through silicon via (TSV) 278 may be used to route signals through a control die 211. The TSVs may be used to transmit signals to the control logic within the control die 211. The TSVs 276, 278 may be formed before, during or after formation of the integrated circuits in the semiconductor dies 201, 211. The TSVs may be formed by etching holes through the wafers. The holes may then be lined with a barrier against metal diffusion. An example material for the barrier is titanium nitride, although a different material may be used. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package. The solder balls 272 may form a part of the interface between integrated memory assembly 207 and memory controller 120.

FIG. 3B depicts a side view of another embodiment of an integrated memory assembly 207 stacked on a substrate 271. The integrated memory assembly 207 of FIG. 3B has three control dies 211 and three memory structure dies 201. In some embodiments, there are many more than three memory structure dies 201 and many more than three control dies 211. In this example, each control die 211 is bonded to at least one memory structure die 201. Optionally, a control die 211 may be bonded to two or more memory structure dies 201.

Some of the bond pads 282, 284 are depicted. There may be many more bond pads. A space between two dies 201, 211 that are bonded together is filled with a solid layer 280, which may be formed from epoxy or other resin or polymer or dielectric material such as silicon oxide, silicon nitride, or other similar dielectric materials. Other similar materials may be used. In contrast to the example in FIG. 3A, the integrated memory assembly 207 in FIG. 3B does not have a stepped offset. A memory die through silicon via (TSV) 276 may be used to route signals through a memory structure die 201. A control die through silicon via (TSV) 278 may be used to route signals through a control die 211.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package.

As has been briefly discussed above, the control die 211 and the memory structure die 201 may be bonded together. Bond pads on each die 201, 211 may be used to bond the two die together. In some embodiments, the bond pads are bonded directly to each other, without solder or other added material, in a so-called Cu-to-Cu bonding process. In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension. Such bonds may be formed at room temperature, though heat may also be applied. In embodiments using Cu-to-Cu bonding, the bond pads may be about 5 μm square and spaced from each other with a pitch of 5 μm to 5 μm. While this process is referred to herein as Cu-to-Cu bonding, this term may also apply even where the bond pads are formed of materials other than Cu.

When the area of bond pads is small, it may be difficult to bond the semiconductor dies together. The size of, and pitch between, bond pads may be further reduced by providing a film layer on the surfaces of the semiconductor die including the bond pads. The film layer is provided around the bond pads. When the die are brought together, the bond pads may bond to each other, and the film layers on the respective die may bond to each other. Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller sizes and pitches.

Some embodiments may include a film on surface of the dies 201, 211. Where no such film is initially provided, a space between the die may be under filled with an epoxy or other resin or polymer or dielectric material such as silicon oxide, silicon nitride, or other similar dielectric materials. Other similar materials may be used. The under-fill material may be applied as a liquid which then hardens into a solid layer. In some embodiments, the oxide layer is deposited by chemical vapor deposition or atomic layer deposition or other techniques. This under-fill step protects the electrical connections between the dies 201, 211, and further secures the die together. Various materials may be used as under-fill material.

FIG. 3C shows another example of a stacked integrated memory assembly 207 (stacked memory assembly) with center connection. While the example of FIG. 3B shows TSVs 276 and 278 located in an edge region of dies 201 and 211 respectively, FIG. 3C shows TSVs 276 and 278 located in a central region of dies 201 and 211, respectively.

FIG. 4 is a perspective view of a portion of one example embodiment of a monolithic three dimensional memory array/structure that can comprise memory structure 202, which includes a plurality non-volatile memory cells arranged as vertical NAND strings. For example, FIG. 4 shows a portion 400 of one block of memory. The structure depicted includes a set of bit lines BL positioned above a stack 401 of alternating dielectric layers and conductive layers. For example purposes, one of the dielectric layers is marked as D. The conductive layers are labeled as one of: SGD, WL, or SGS. An SGD conductive layer serves as drain side select lines. A WL conductive layer serves as a word line. An SGS conductive layer serves as a source side select line. The numbers of each of these conductive layers is limited for ease of illustration. The number of alternating dielectric layers and conductive layers can vary based on specific implementation requirements. Below the alternating dielectric layers and word line layers is a source line layer SL. Memory holes are formed in the stack of alternating dielectric layers and conductive layers. For example, one of the memory holes is marked as MH. Note that in FIG. 4, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data. More details of the three dimensional monolithic memory array that comprises memory structure 202 is provided below.

In one embodiment the block is operated as a number of “sub-blocks.” Each of these “sub-blocks” has many NAND strings. In an embodiment, an isolation region (IR) divides the SGD layers into multiple SGD select lines, each of which is used to select a sub-block (e.g., set of NAND strings). FIG. 4 depicts an example having one IR region and thereby two sub-blocks. However, there may be more than one IR region and thereby more than two sub-blocks. Optionally, the IR region can extend down through all of the alternating dielectric layers and conductive layers.

FIG. 4A is a block diagram explaining one example organization of memory structure 202, which is divided into four planes 403-A, 403-B, 403-C, 403-D. Each plane is then divided into M physical blocks. In one example, each plane has about 2000 physical blocks (or more briefly “blocks”). However, different numbers of blocks and planes can also be used. In one “full-block” embodiment, a block of memory cells is a unit of erase. That is, all memory cells of a block are erased together. In a “sub-block mode” embodiment, blocks are divided into sub-blocks and the sub-blocks are the unit of erase. In an embodiment, a block contains a number of word lines with each sub-block containing a unique set of the data word lines. Memory cells can also be grouped into blocks for other reasons, such as to organize the memory structure to enable the signaling and selection circuits. In some embodiments, a block represents a groups of connected memory cells as the memory cells of a block share a common set of word lines. For example, the word lines for a block are all connected to all of the vertical NAND strings for that block. Although FIG. 4A shows four planes 403 more or fewer than four planes can be implemented. In some embodiments, memory structure 202 is an extreme multi-plane architecture with, for example, 32, 64, 128 or some other large number of planes. In some embodiments, programming and reading can be performed in parallel in a selected block in each plane 403.

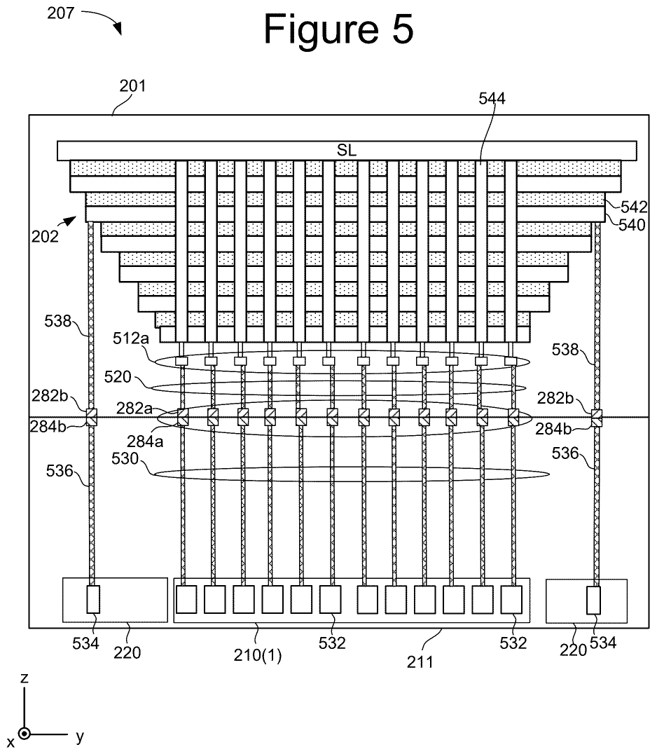

FIG. 5 depicts a control die 211 bonded to a memory die 201 to form an integrated memory assembly 207. The memory structure 202 has a stack of conductive layers 540 alternating with dielectric layers 542. NAND strings 544 are formed in the stack. The NAND strings 544 extend in the z-direction. Bit lines 512a reside in a metal layer adjacent to the stack. The control die 211 has row control circuitry 220, column control circuitry 210(1) and system control logic 260 (not shown in this view). The column control circuitry 210(1) has column circuits 532. Each column circuit 532 may include a sense amplifier and/or bit line driver. In some embodiments, the sense amplifier contains the bit line driver. Each particular column circuit 532 is electrically connected to a bit line of bit lines 512a. Each pathway includes a control die via structure 530 that connects the particular column circuit 532 to a control die bond pad 284a. A bit line contact/via 520 connects the memory die bond pad 282a to the bit line 512a. The bit line contact/via 520 and control die via structure 530 are examples of the electrical paths 206 that provide electrical connection between column decoder 212, driver circuitry 214, and block select 216 and bit lines of memory structure 202 (see FIGS. 2A, 2B).

FIG. 5 also depicts example connections between word line drivers 534 and the memory structure 202. The memory structure 202 has a staircase structure at two edges to allow connections to be made to conductive layers 540. The conductive layers 540 may include word lines and select lines. A word line driver 534 in the row control circuitry 220 is connected to a die bond pad 284b by way of a via structure 536. Staircase via structure 538 connects memory die bond pad 282b to a conductive layer 540. Connections from other word line drivers 534 to other conductive layers 540 are not visible in FIG. 5. The via structures 536 and staircase via structure 538 are examples of the electrical paths 208 that provide electrical connection between row decoder 222, array drivers 224, and block select 226 to memory structure 202 (see FIGS. 2A, 2B). In some cases, an integrated memory assembly such as integrated memory assembly 207 may be combined with one or more additional integrated memory assemblies to form a larger assembly, which may store a large amount of data.

Additional circuits (not shown in FIG. 5) may be present in control die 211 (e.g., some or all of the circuits shown in control die 211 of FIG. 2B). For example, the system control logic 260 is not depicted in FIG. 5. The system control logic 260, column control circuity 210, and row control circuitry 220 may be formed on a crystalline silicon substrate. In an embodiment, through silicon vias (TSVs) extend through the crystalline silicon substrate. In an embodiment, the TSVs each have a conductive column surrounded by a low-k dielectric such as an air gap.

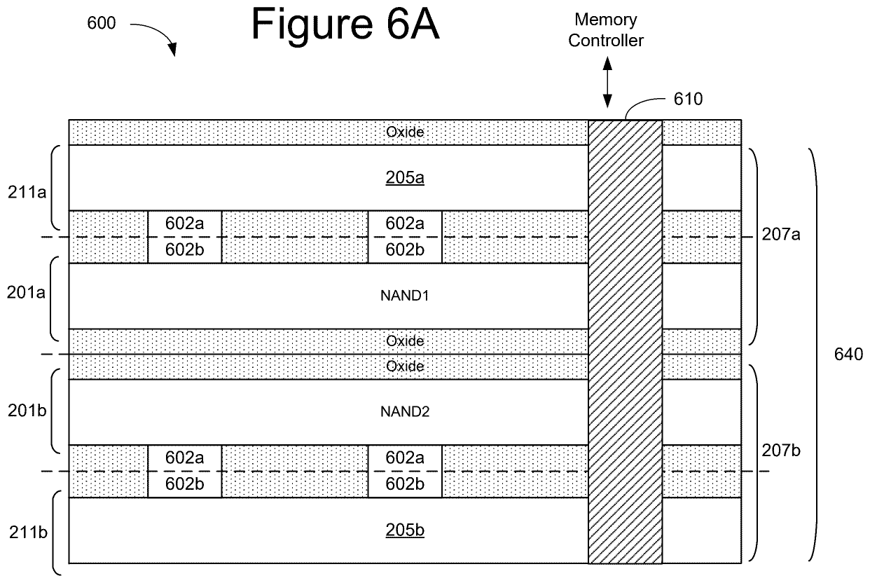

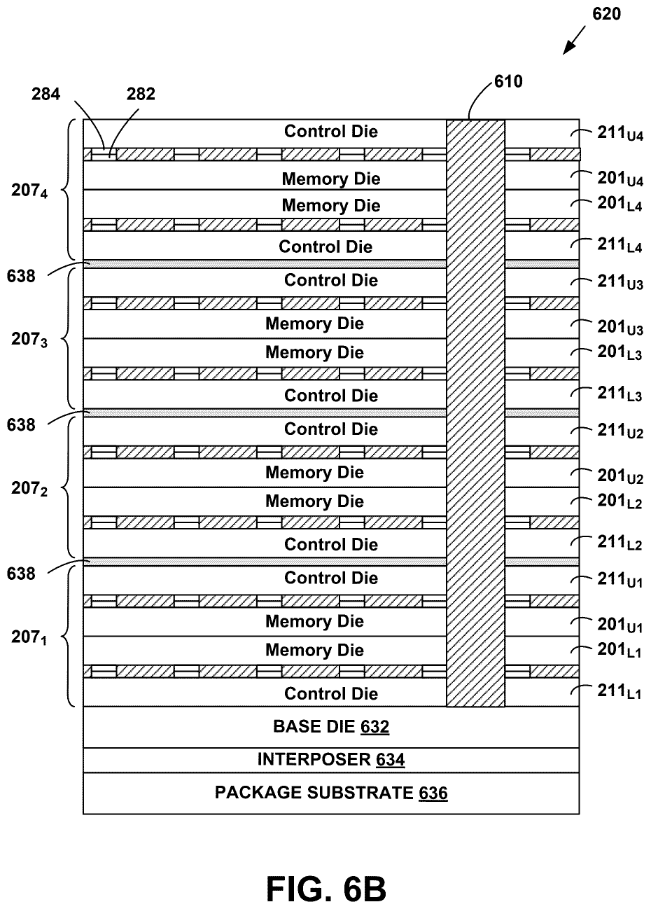

FIG. 6A illustrates an embodiment of a “mirror die pair”. The mirror die pair has a first semiconductor substrate 205a, a first NAND structure (NAND1), a second semiconductor substrate 205b, and a second NAND structure (NAND2). In an embodiment depicted in FIG. 6A, the mirror die pair is formed from two integrated memory assembly 207. However, the mirror die pair could alternatively be formed from two memory dies 200. The mirror die pair in FIG. 6A, has first integrated memory assembly 207a, which is formed of a memory die 201a and a control die 211a (e.g., integrated memory assembly 207, formed of memory die 201 and control die 211). Control die 211a includes control circuits formed on a silicon substrate 205a. The control circuits may include, for example, system control logic 260, column control circuity 210, and row control circuitry 220. First integrated memory assembly 207a is inverted compared with integrated memory assembly 207 of FIG. 5, with control die 211a above memory die 201a. A second integrated memory assembly 207b is formed of memory die 201b and control die 211b and is located below first integrated memory assembly 207a. Control die 211b includes control circuits formed on silicon substrate 205b. Theses control circuits may include, for example, system control logic 260, column control circuity 210, and row control circuitry 220. Second integrated memory assembly 207b is oriented similarly to integrated memory assembly 207 in FIG. 5 so that first and second integrated memory assemblies 207a and 211b are in a mirror-image arrangement (e.g., mirror image about a plane between integrated memory assemblies 207a and 211b) and together may be considered to form a mirrored die pair 640. First and second integrated memory assemblies 207a and 211b may be bonded together (bond pads between first and second integrated memory assemblies 207a and 211b are not shown in FIG. 6A). In some cases, two or more mirrored die pairs may be combined (e.g., stacked) in a single memory system (e.g., in alternating orientation such that the orientation of even numbered integrated memory assemblies is opposite to orientation of odd numbered integrated memory assemblies).

Deep trench contacts (DTCs) 610 extend through the stack. The DTCs include TSVs that run through the first silicon substrate 205a and the second silicon substrate 205b. The DTCs 610 also run through oxide. The DTCs include a number of electrical pathways that allow communication with a device outside the stack such as the memory controller 120. Thus, the DTCs 610 permit communication between control circuits on a control die 211 and a sender or receiver that is external to the die on which the control circuitry resides. Note that there may be a number of mirror die pairs 600 in a stack such that the DTCs 610 in the mirror die pair 600 in FIG. 6A may connect to DTCs 610 other mirror die pairs 600. However, the electrical pathways still permit communication with the memory controller (or other sender/receiver). The relatively long length of the DTCs 610 through one or stack of the mirror die pairs 600 presents technical challenges with respect to signal integrity on the electrical pathways in the DTCs. In an embodiment, a low-k dielectric (e.g., air) surrounds the electrical pathways in the DTCs 610 to mitigate issues with capacitive coupling.

Each control die 211a, 211b also has electrical pathways 602a that reside in a dielectric such as silicon dioxide. The electrical pathways 602a may reside in a number of “metal layers” in the silicon dioxide. The electrical pathways 602a may include control die via structures 530, 536. Each memory die 201a, 201b has electrical pathways 602b that reside in a dielectric such as silicon dioxide. The electrical pathways 602b may reside in a number of “metal layers” in the silicon dioxide. The electrical pathways 602b may include bit line contact/via 520 and staircase via structures 538. Bond pads may physically and electrically connect the electrical pathways 602a of a control die 211 to the electrical pathways 602b of a memory die 201. The bond pads are not depicted in FIG. 6A.

In embodiments, multiple integrated memory assemblies 207 of FIG. 6A may be vertically stacked together and packaged in a memory package, e.g., to increase the memory capacity of each memory package. For example, FIG. 6B depicts a simplified diagram of an embodiment of a vertical stack 600 of four integrated memory assemblies 207₁, 207₂, 207₃, and 207₄. In an embodiment, integrated memory assemblies 207₁, 207₂, 207₃, and 207₄ are disposed on a base die 632, which in turn is disposed on an interposer 634 and a package substrate 636, all without a stepped offset. In embodiments, a solid layer 638 (e.g., an epoxy or other resin or polymer or dielectric material such as silicon oxide, silicon nitride, or other similar dielectric materials. Other similar material may be used) is disposed between adjacent integrated memory assemblies 207. Persons of ordinary skill in the art will understand that more or fewer than four integrated memory assemblies 207 may be stacked together and included in a memory package.

The base die 632 could include a memory controller 120 such as the memory controller of FIG. 1. The memory controller 120 communicates with the integrated memory assemblies 207₁, 207₂, 207₃, and 207₄ over electrical pathways in the DTCs 610. The DTCs 610 extend through the stack 600. Each integrated memory assembly 207 contains one or more control die and one or more memory die. In this example, each integrated memory assembly 207 contains two control dies and two memory dies, but more or fewer than two of each type of die may be present in an integrated memory assembly. Each control die has a crystalline silicon substrate on which control circuitry is formed. The control circuitry is used for die level control one of the memory die. Each memory die contains one or more memory structures with memory cells. The memory cells may be non-volatile or volatile. In one embodiment, the memory cells are NAND memory cells. Examples in which the memory cells are NAND will be discussed herein; however, the memory cells are not limited to NAND. Other types of memory for the memory dies include, but are not limited to, NOR-type flash memory, ReRAM, MRAM, FeRAM, PCM, SRAM, and DRAM. Note that the memory dies are not required to all be of the same type of memory. For example, some memory dies could contain NAND cells with one or more other memory die containing DRAM. The control circuitry applies signals to the memory structure in the memory die to control the memory structure. For example, the control circuitry applies voltages to word lines and bit lines to control NAND memory cells. However, the memory cells are not required to be NAND. The control circuitry is also able to sense the memory cells. The memory die are not required to have a crystalline semiconductor substrate; however, optionally a memory die could also include a crystalline semiconductor substrate. The DTCs 610 may include TSVs that run through the crystalline semiconductor substrate in all or most of the control die. In one embodiment the DTCs 610 are not required to extend entirely through the crystalline semiconductor substrate of the control die 211_{U4} that is furthest from the base die 632. If the memory die also have crystalline semiconductor substrates, then the DTCs 610 may also include TSVs that run through the crystalline semiconductor substrate in each memory die. The DTCs 610 also extend through an insulator such as silicon oxide. In an embodiment, the DTCs 610 have conductive pathways (e.g., columns), with a least a portion of each conductive pathways surrounded by a low-k dielectric such as an air gap. The low-k dielectric mitigates issues with capacitive coupling between the conductive pathways to thereby improve signal integrity for signals transferred over the DTCs 610 between the base die 632 (e.g., memory controller 120) and the integrated memory assemblies 207₁, 207₂, 207₃, and 207₄.

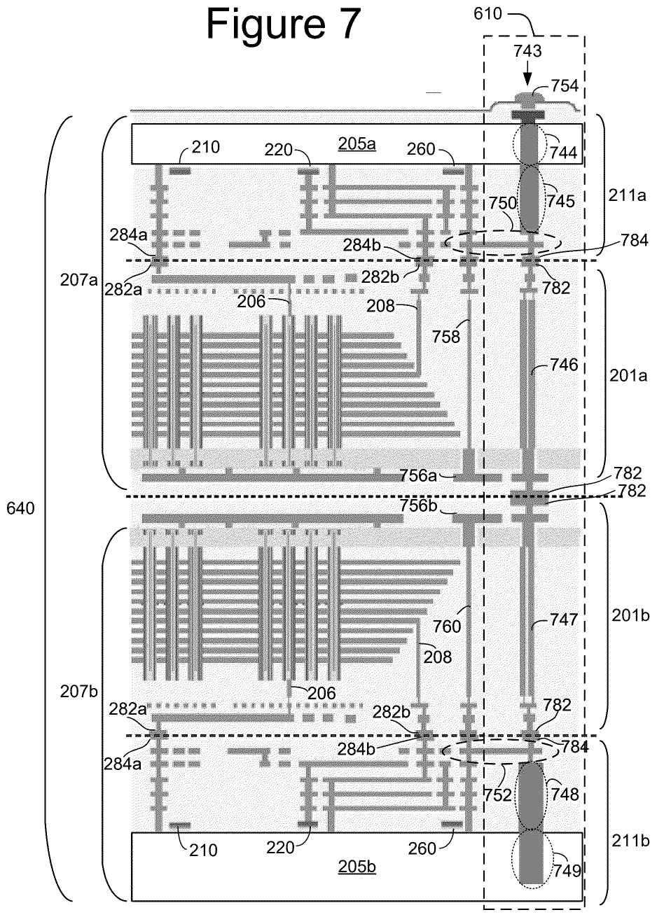

FIG. 7 illustrates an example of mirrored die pair 640, which includes a Deep Trench Contact (DTC) region 610 that extends through stacked integrated memory assemblies 207a and 211b and includes DTCs that connect between components (e.g., between integrated memory assemblies 207a, 211b and/or additional components that may be provided in the stack or adjacent to the stack). The DTC region 610 contains a number of Deep Trench Contacts (DTCs). In general, the DTCs extend from top to bottom of the DTC region 610. The DTCs contain electrical pathways that are individually surrounded by a low-k dielectric to mitigate capacitive coupling. Note that an individual electrical pathway is not required to extend all of the way through the DTC region 610 in order to provide for signal communication with its target. One of the DTCs 743 is depicted in the DTC region 610, but there are many more DTCs in the DTC region. A contact 754 may connect the DTC 743 to another mirrored die pair 640 or to, for example, the base die 632. The DTC 743 is shown as having a few sections (e.g., vias), depending on factors such as the type of material in which the DTC resides. A portion of the DTC 743 is a Through Silicon Via (TSV) 744 that extends entirely through a crystalline silicon (or other semiconductor for the substrate discussed above) substrate of control die 211a. The DTC 743 also has DTC via 745 in silicon oxide region of control die 211a, DTC via 746 in silicon oxide region of memory die 201a, DTC via 747 in silicon oxide region of memory die 201b, DTC via 748 in silicon oxide region of control die 211b and DTC via 749 in crystalline silicon substrate of control die 211b. In this example the DTC via 749 in crystalline silicon substrate of control die 211b is a deep trench contact, as it does not pass entirely through the crystalline silicon substrate. However, the DTC via 749 could optionally be a TSV that passes entirely through the crystalline silicon substrate of control die 211b. Any, or all, of the vias of the DTC 743 may have a conductive column surrounded by a low-k dielectric such as, but not limited to, an air gap. For example, any or all of TSV 744, via 745, via 746, via 747, via 748, and/or via 749 may have a conductive column surrounded by a low-k dielectric such as, but not limited to, an air gap.

As noted, there may be many DTCs in DTC region 610, wherein the low-k dielectric mitigates capacitive coupling issues between the electrical pathways in DTC region 610. Therefore signal integrity of signals transmitted in the DTC region 610 is improved. These signals may include, for example, data and address signals, command signals, supply voltages, etc. Note that each DTC may include multiple vias (including, but not limited to TSVs) connected in series (e.g., by bonding between dies). For example, pairs of bond pads 782, 784 at interfaces between dies may be used to connect the multiple vias of the DTC 743.

A DTC may be connected to electrical circuits in one or more die in a stack. For example, FIG. 7 shows DTC 743 connected to circuits of control die 211a by connection 750 (e.g., a metal wire or trace), which extends from DTC via 745 in DTC region 610 and connects to control circuitry of control die 211a. The control circuitry may include system control logic 260, column control circuitry 210, and row control circuitry 220, each of which may be formed on the respective semiconductor substates 205a, 205b. In an embodiment, the semiconductor substates 205a, 205b are crystalline silicon substrates. In an embodiment, the system control logic 260 receives signals (e.g., data, addresses, commands) that were transmitted over the DTCs by, for example, the memory controller 120. The system control logic 260 may also transmit signals (e.g., data) over the DTCs to, for example, the memory controller 120.

FIG. 7 shows DTC 743 connected to circuits of control die 211b by connection 752, which extends from DTC via 748 in DTC region 610 and connects to one or more logic circuit of control die 211b. DTC 743 further includes a contact pad or bump 754, which may be used to connect DTC 743 to one or more additional circuits (e.g., a circuit outside the stack of mirrored die pairs). While specific connections to control dies 211a and 211b are shown, DTCs may be connected in any desired configuration to any one or more die (e.g., control die(s) and/or memory die(s)) in order to provide desired electrical connections to provide supply voltages, commands, user data, address data and/or any other electrical signals that may be appropriate.

A DTC may also be connected to the memory die 201. For example, FIG. 7 shows DTC 743 connected to element 756a in memory die 201a by connection 750 and via 758. Similarly, FIG. 7 shows DTC 743 connected to element 756b in memory die 201b by connection 752 and via 760. As an example, a voltage such as source line voltage could be provided to element 756a, 756b in the respective memory dies 201a, 201b.

In some cases, two or more mirrored die pairs (e.g., mirrored die pair 640) may be combined in a stacked arrangement to form a stack of integrated memory assemblies that have alternating orientations (e.g., similar to integrated memory assemblies 207a and 211b). A DTC region may extend through such a stack and may include DTCs that enable access to memory cells in individual mirrored die pairs in the stack (e.g., by accessing memory cells in each memory die via control circuits in a corresponding control die of an integrated memory assembly).

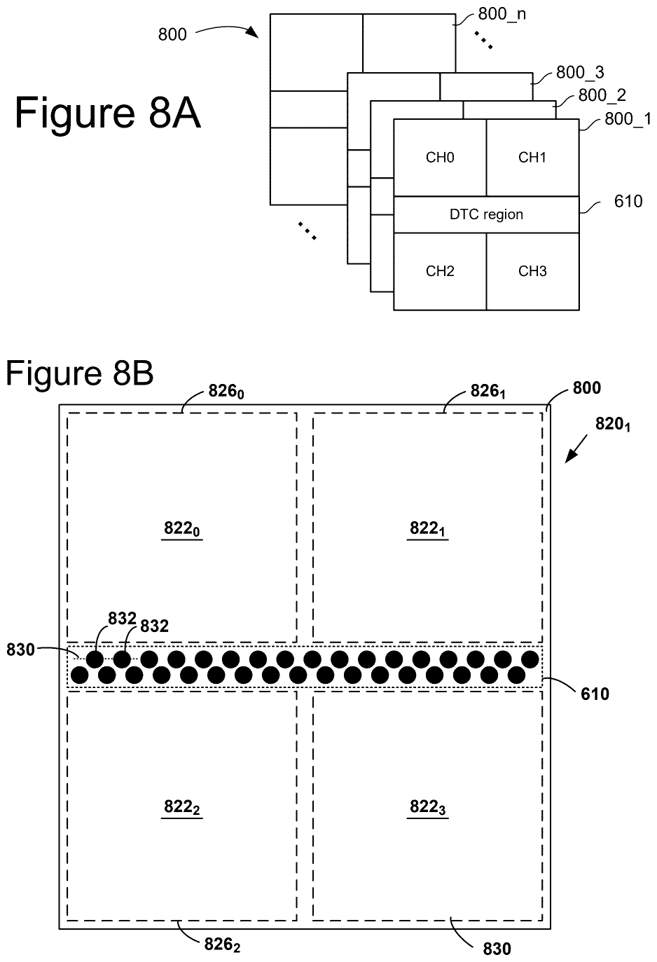

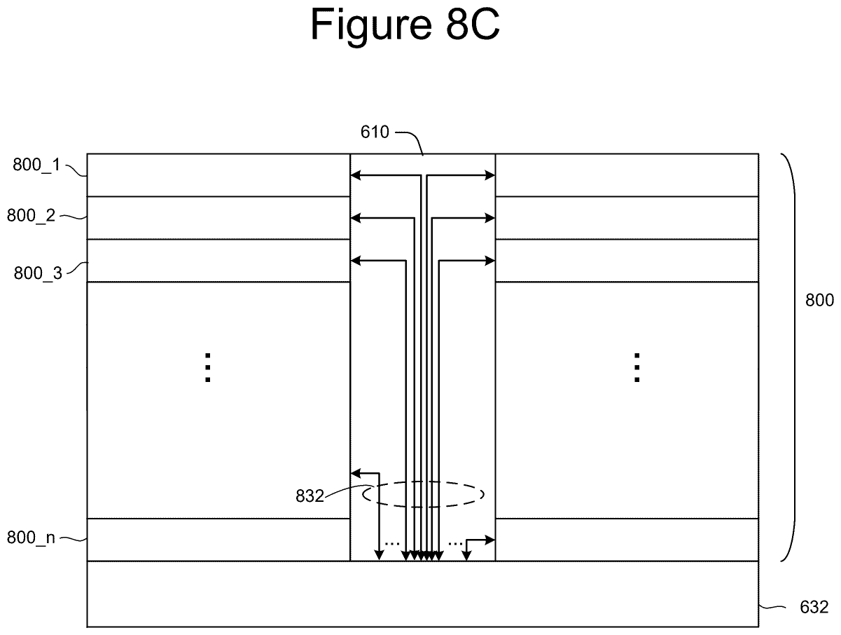

FIG. 8A shows an example of a stack 800 of mirrored die pairs 800_1 to 800_n in exploded view. The number of mirrored die pairs, n, in such a stack may be, for example, 4, 8, 16 or some other number. Each mirrored die pair may include a DTC region to enable communication of signals between a memory controller (not depicted in FIG. 8A) and each of the memory die pairs. For example, mirrored die pair 800_1 includes DTC region 610. Communication of signals through the memory die pairs is susceptible to capacitive coupling issues. In an embodiment, the conductive pathways (e.g., deep trench contacts, vias, TSVs, etc.) in the DTC region of each of the memory die pairs are individually surrounded by a low-k dielectric (e.g., air gap), which mitigates capacitive coupling issues.

On either side of DTC region 610 are areas CH0 to CH3, which correspond to four channels that may be configured to allow some degree of independent operation of each channel. In an example, memory dies in mirrored die pair 800_1 include an equal number of planes in each area CH0 to CH3 (e.g., four, eight, sixteen, thirty-two, sixty-four or some other number of planes per channel) and control dies in mirrored die pair 800_1 include corresponding control circuits in each channel area CH0 to CH3 (e.g., circuits in CH0 area of a control die are connected to planes of CH0 in the memory die that is bonded to the control die). Mirrored die pairs 800_1 to 800_n may be identical so that each mirrored die pair has a similar structure, which may be as illustrated with respect to mirrored die pair 640 or otherwise. In some cases, mirrored die pairs in a stack may differ in one or more respects. While DTC region 610 is shown at a particular location, the location and dimensions of a DTC region are not limited to the example shown (e.g., DTC region may extend along die edges). In some cases, multiple separate DTC regions may be provided.

FIG. 8B is a simplified diagram of a top view of an embodiment of mirror die pair 800_1 in FIG. 8A. In an embodiment, mirror die pair 800_1 includes four regions 822₀, 822₁, 822₂, and 822₃, and also includes a DTC region 610. The four regions 822₀, 822₁, 822₂, and 822₃ correspond to the four channels (CH0, CH1, CH2, CH3) in FIG. 8A. Persons of ordinary skill in the art will understand that each mirror die pair may include more or fewer than four channels, and thus mirror die pair alternatively may include more or fewer than four regions 822₀, 822₁, 822₂, and 822₃.

In an embodiment, DTC region 610 includes DTCs 832 disposed throughout DTC region 610. In an embodiment, DTCs 832 extend vertically through memory die pair in a stack 800. In an embodiment, DTCs 832 may be formed by etching vertical columns through memory die pairs, and then forming a conductive material within each vertical column. In embodiments, DTCs 832 may contain conductive columns formed from metals, metal alloys, silicon-metal alloys, binary, ternary compounds, such as copper, tungsten, copper-tin, other copper-based alloys, tungsten-silicide alloys, nickel-silicide alloys, and other similar materials. In an embodiment, each conductive column is surrounded by a low-k dielectric such as an air gap.

FIG. 8C provides a schematic illustration of DTCs 832 extending through DTC region 610, which extends through mirrored die pairs 800_1 to 800_n in stack 800. DTCs 832 may connect memory controller die 632 with mirrored die pairs 860_1 to 860_n and may include a number of DTCs to provide supply voltages, clock signal(s), commands, user data, address data and/or other electrical signals. Note that at least some of the DTCs 832 will extend from memory controller die 632 to the last mirrored die pairs 800_1. However, it is not required that all DTCs 832 extend from the memory controller die 632 to the last mirrored die pairs 800_1. However, each DTC 832 will extend sufficiently through DTC region 610 to permit communication between the memory controller die 632 and at least one of the mirrored die pairs 800_1 to 800_n in stack 800.

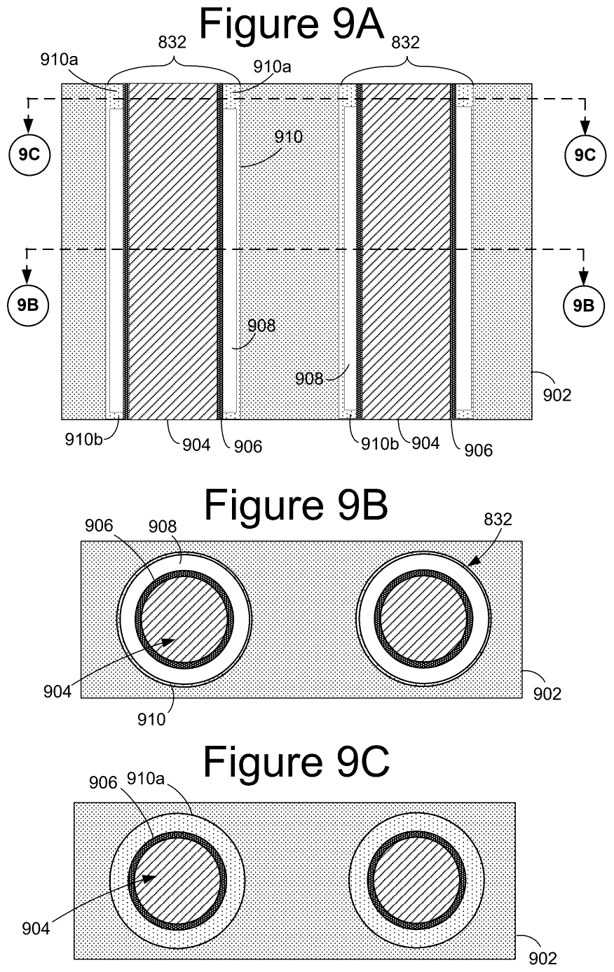

FIG. 9A is a cross-sectional view of a portion of two DTCs 832 in a semiconductor substrate 902. The semiconductor substrate 902 may be a crystalline silicon substrate. Other crystalline semiconductor substrates such as Group-IV, Group III-V, Group II-VI, etc. can be used. Example crystalline semiconductors for the substrate include, but are not limited to, Germanium, Gallium Arsenide, Indium Phosphide, Cadmium Selenium, etc. FIG. 9A is a cross-section along line 830 in FIG. 8B for a portion of the two DTCs 832 that reside in a semiconductor substrate 902, such as a silicon substrate of a die. FIG. 9B is a cross-section along line 9B-9B in FIG. 9A. FIG. 9C is a cross-section along line 9C-9C in FIG. 9A. The portion of the pair of DTCs 832 that is depicted reside in a semiconductor substrate 902. The pair of DTCs 832 may extend entirely through the silicon substrate 902 and thus be referred to as TSVs. The semiconductor substrate 902 may be, but is not limited to, the silicon substrate in a control die 211. The DTCs 832 each have a conductive column 904 in the center. The conductive column 904 is formed from a conductive material such as copper, although other conductive materials such as aluminum, tin, nickel, gold, doped polysilicon, metal-alloys, Si-metal-alloys, binary or ternary compounds or combinations thereof may be used. A barrier layer 906 surrounds the conductive column 904. The barrier layer 906 may include, for example, titanium nitride, titanium, titanium/titanium nitride bilayer, although a different material may be used in the barrier layer 906. An air gap 908 surrounds the barrier layer 906. The air gap has a low dielectric permittivity compared to the dielectric permittivity of silicon dioxide (SiO₂). In another embodiment, instead of an air gap 908 a dielectric material having a low dielectric permittivity surrounds the barrier layer 906. There may be a thin silicon dioxide 910 on the inside surface of the semiconductor substrate 902. Thus, the thin silicon dioxide 910 on the inside surface of the semiconductor substrate 902 is next to the air gap 908. There may also be a silicon dioxide top cap 910a at the top of the air gap 908 and a silicon dioxide bottom cap 910b at the bottom of the air gap 908.

The low permittivity dielectric (whether air or another low permittivity dielectric) overcomes problems associated with capacitive coupling effects associated with the conductive columns. FIGS. 10A and 10B show an embodiment in which the DTCs 832 have a low permittivity dielectric without an air gap. FIG. 10A is a cross-section along line 830 in FIG. 8B for a portion of the two DTCs 832 that reside in a substrate, such as a silicon substrate of a die. FIG. 10B is a cross-section along line 10B-10B in FIG. 10A. The DTCs 832 each have a conductive column 904 in the center. The conductive column 904 is formed from a conductive material such as copper, although other conductive materials such as aluminum, tin, nickel, gold, doped polysilicon, metal-alloys, Si-metal-alloys, binary or ternary compounds or combinations thereof may be used. A barrier layer 906 surrounds the conductive column 904. The barrier layer 906 may be, for example, titanium nitride, titanium, titanium/titanium nitride bilayer, or other nitride based barrier layers, for example tungsten nitride/tungsten, etc. A dielectric material 1002 having a low dielectric permittivity surrounds the barrier layer 906.

The dielectric material 1002 has a dielectric permittivity less than silicon dioxide. In general, the dielectric permittivity may be greater than 1 but less than 3.9. For example, the dielectric permittivity may be between 1.1 and 3.8. A wide range of materials may be used for the dielectric material 1002. The dielectric material 1002 could be inorganic (e.g., fluorinated glass (SiOF), hydrogen silesquioxane (HSQ)), organic (e.g., Poly(arylene ether) PAE, Polyimides/Flourinated, Parylene-N/Parylene-F, B-stage polymers, DLC-Diamond-like Carbon /lourinated, Amorphous C/Flourinated, PTFE (Teflon)), an inorganic/organic hybrid (e.g., Si—O—C polymers (e.g. MSQ)). The dielectric material 1002 could be porous (e.g., highly porous oxides, Xerogels/Aerogels, porous MSQ, porous PAE, porous SLIK, porous SiO₂). The dielectric material 1002 could be an oxide derivative (e.g., F-doped oxides, C-doped oxides, H-doped oxides).

FIG. 10A shows some resistors and capacitors to represent the capacitive coupling effects (RC components). The resistors Rm represent the resistance of the conductive columns 904. The resistor Rs represent the resistance of the silicon substrate 902. The capacitors Cd and Cs represent parasitic capacitances. The capacitance of these parasitic capacitances Cd, Cs depends in part on the permittivity of the dielectric material 1002. If the dielectric material 1002 were to be formed with a higher dielectric material such as silicon dioxide (SiO2) then the capacitances Cd, Cs could result in capacitive coupling that is detrimental to operation, especially signal transfer along the conductive columns 904. Using a low permittivity dielectric (whether air or another low permittivity dielectric) mitigates problems associated with capacitive coupling effects. The capacitive coupling effects may cause interference between the signals transmitted on neighbor conductive columns 904. Such interference may have adverse effects on data signals, power signals, control signals, etc. Such interference may impede performance, power, bandwidth, etc. The memory cells may be used to store user data in which case the interference could cause errors in data transmitted from the memory controller 120 through the DTCs to be programmed into the memory cells or could cause errors in data read from the memory cells and sent through the DTCs to the memory controller 120. The memory cells may be used as part of an inference engine in which case the interference may lead to inference errors. Also, the capacitances Cd, Cs may increase RC delay. Applications including, but not limited to, AI inference need high bandwidth. However, the RC delay can reduce the bandwidth for data read from the memory cells. Other potential concerns are unrepairable data-corruption (die/plane level), losing computed inference (decision) information that computed several days-, weeks-and months including obsolete of the whole cube in the usage.

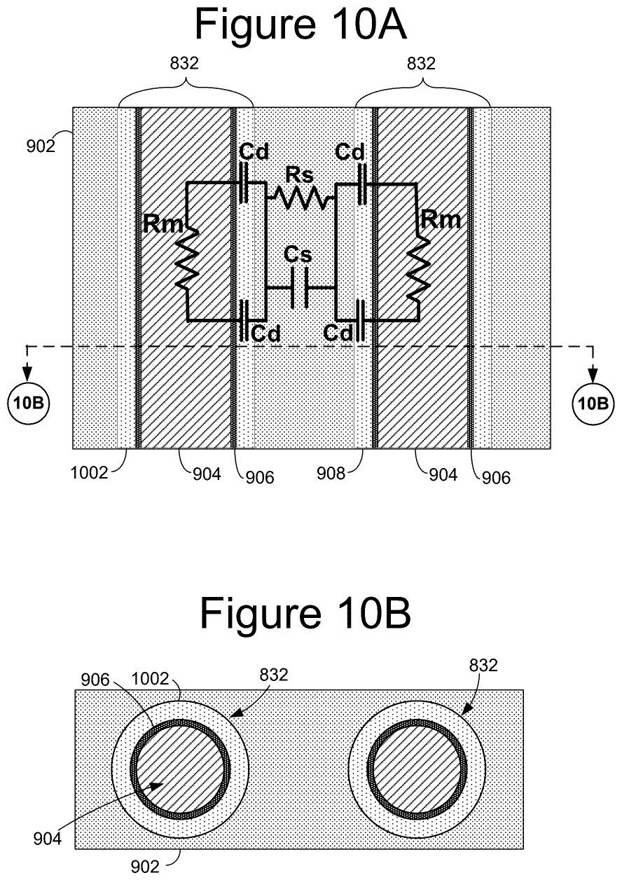

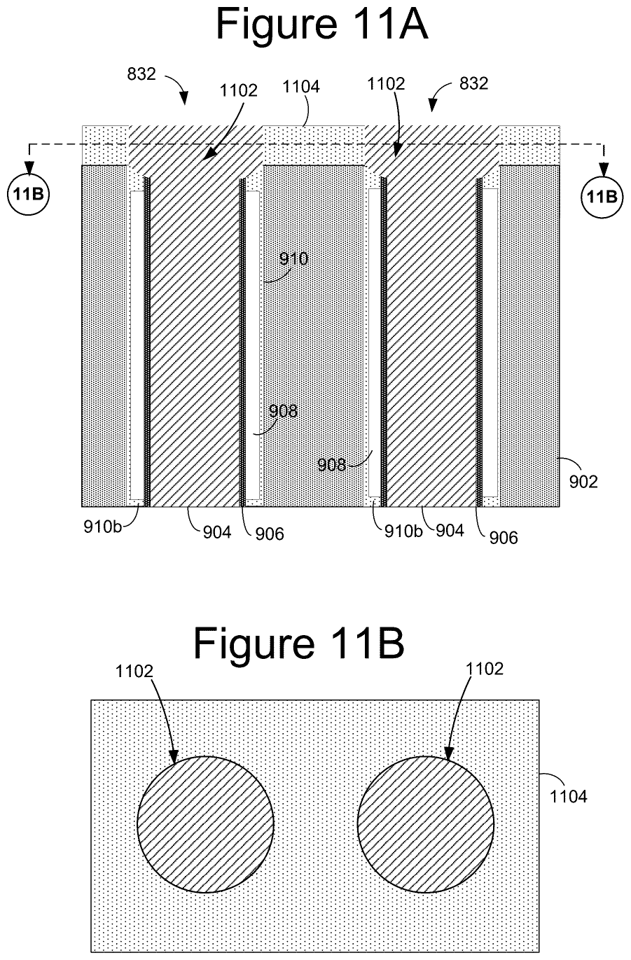

FIG. 11A is a cross-sectional view of a portion of two DTCs 832 in a substrate 902. FIG. 11A is a cross-section along line 830 in FIG. 8B for a portion of the two DTCs 832 that reside in a substrate, such as a silicon substrate of a die. FIG. 11B is a cross-section along line 11B-11B in FIG. 11A. The two DTCs 832 in FIG. 11A are similar to those in FIG. 9A; however, FIG. 11A shows a microbump 1102. The microbump 1102 is physically and electrically in direct contact with the conductive column 904. The microbump may be surrounded by silicon oxide 1104 or another insulator. The microbump 1102 and insulator 1104 may reside at a surface of the control die 211. In some embodiments, the oxide layer 1104 is deposited by chemical vapor deposition or atomic layer deposition or other techniques. The microbump 1102 may be used to form a physical and electrical connection to a conductive column in another control die 211.

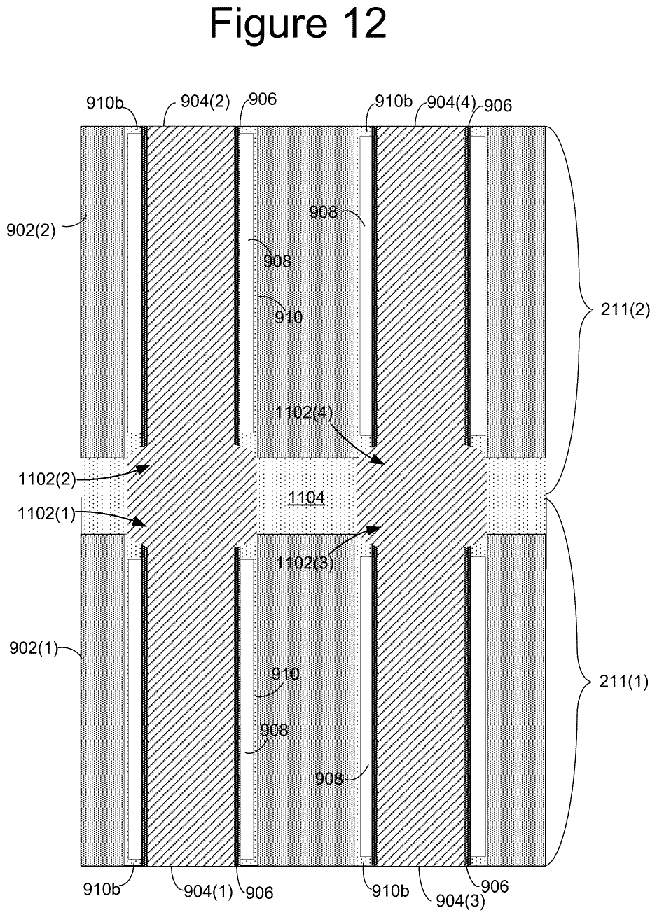

FIG. 12 is a cross-sectional diagram of a portion of two DTCs 832 in silicon substrates of two control dies 211 bonded together. The two control dies 211(1), 211(2) are flipped relative to each other such that microbumps 1102 of control die 211(1) align with the microbumps 1102 of control die 211(2). Specifically, microbump 1102(1) of control die 211(1) connects to microbump 1102(2) of control die 211(2). Therefore, a conductive column 904(1) in semiconductor substrate 902(1) on control die 211(1) electrically connects to a conductive column 904(2) in semiconductor substrate 902(1) on control die 211(2). Similarly, microbump 1102(3) of control die 211(1) connects to microbump 1102(4) of control die 211(2). Therefore, a conductive column 904(3) in substrate 902(1) on control die 211(1) electrically connects to a second column 904(4) in substrate 902(1) on control die 211(2). The microbumps may be surrounded by silicon oxide 1104 or another insulator. In some embodiments, the oxide layer 1104 is deposited by chemical vapor deposition or atomic layer deposition or other techniques. In this example, the two DTCs 832 extend entirely through a crystalline silicon substrate 902(1), 902(2) and are referred to as TSVs. Each TSV may connect to DTCs (e.g., vias) that extend through silicon dioxide in the respective control dies 211(1), 211(2) (see, for example, FIG. 7).

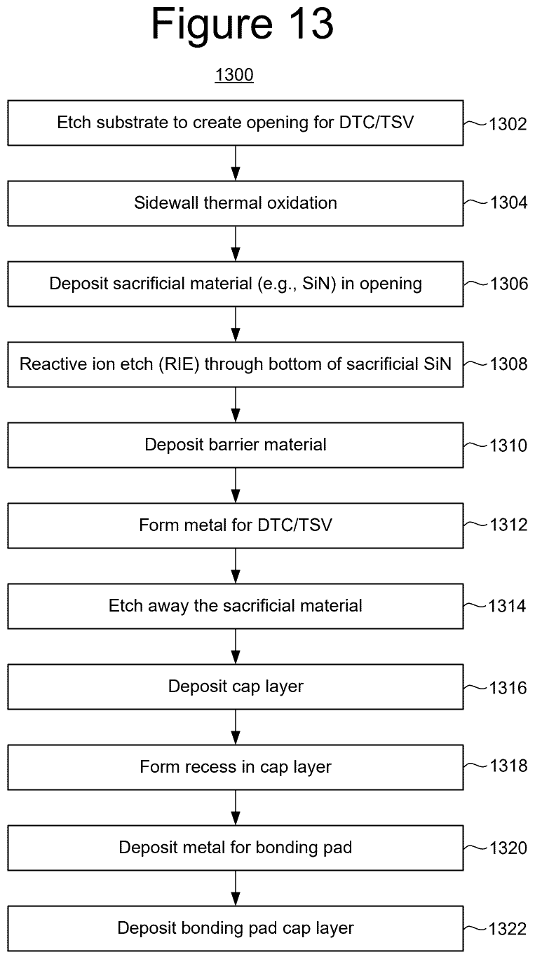

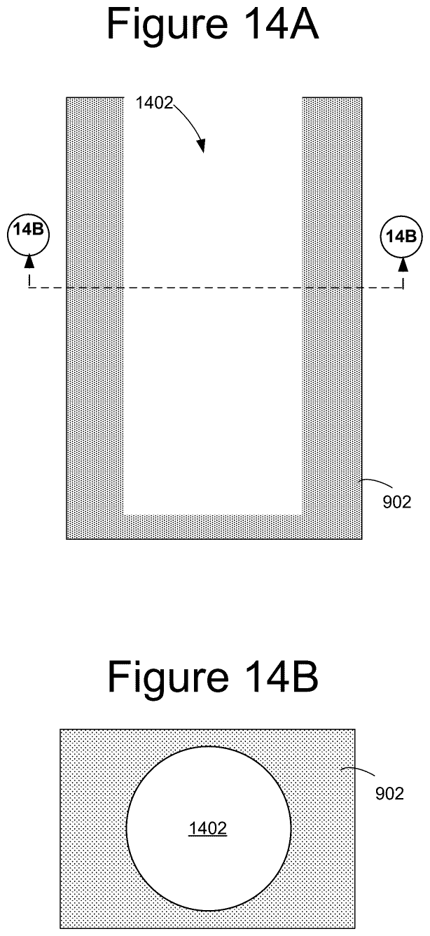

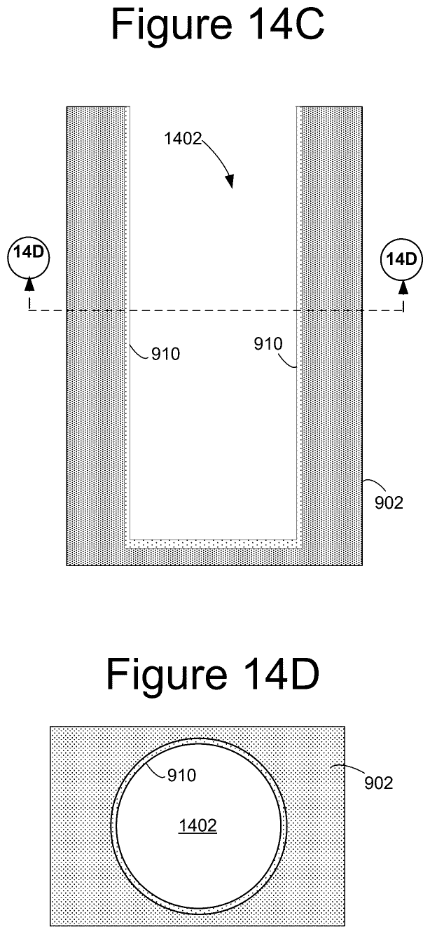

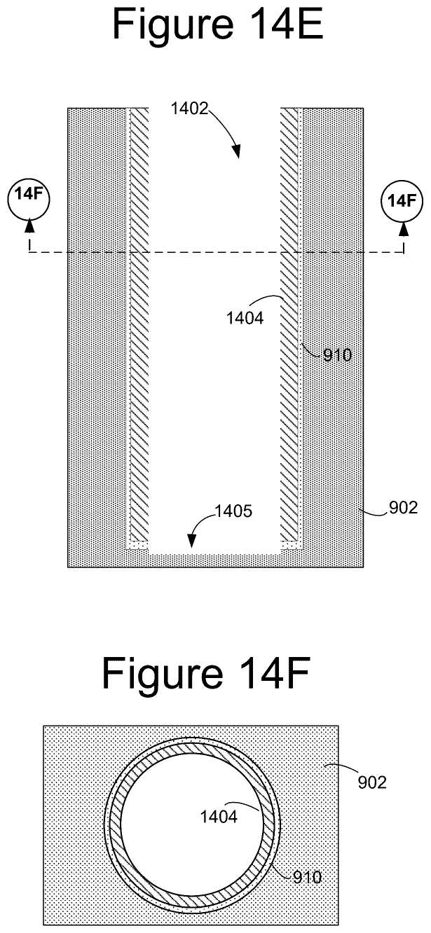

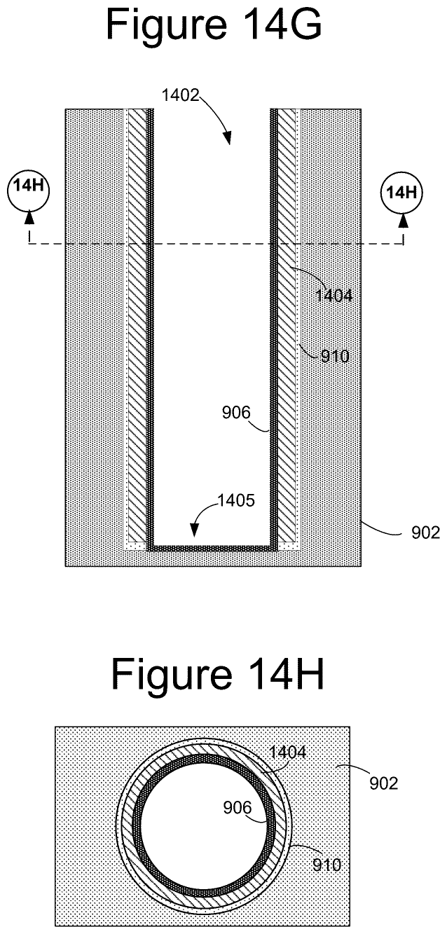

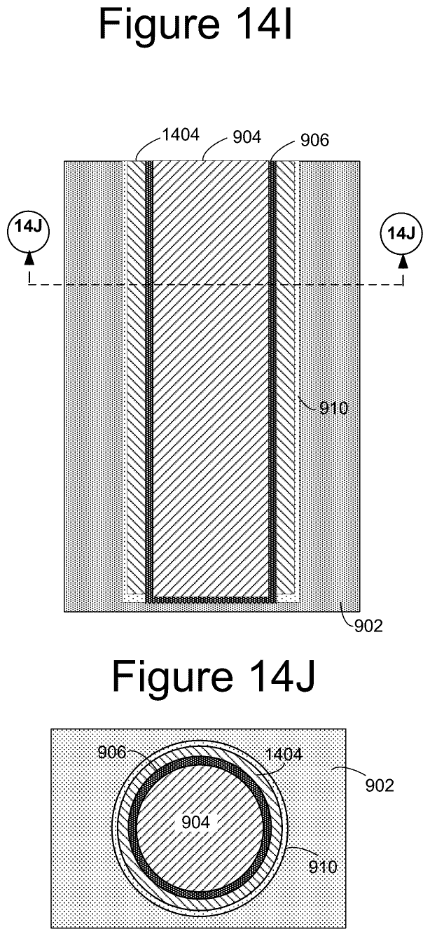

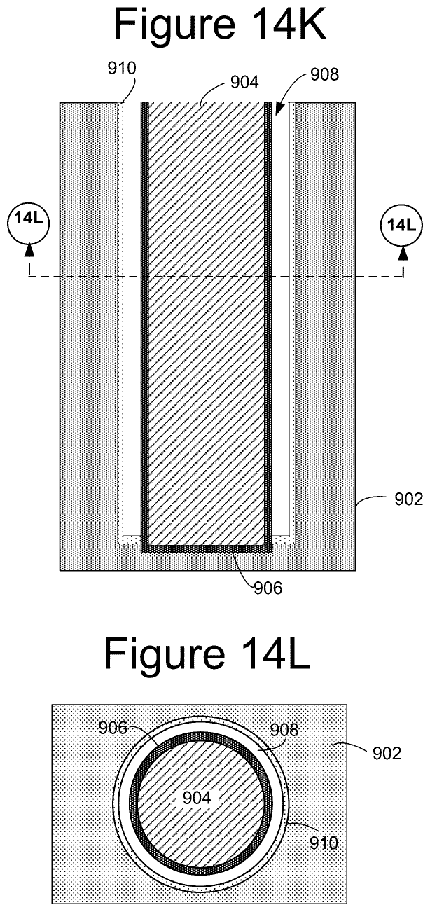

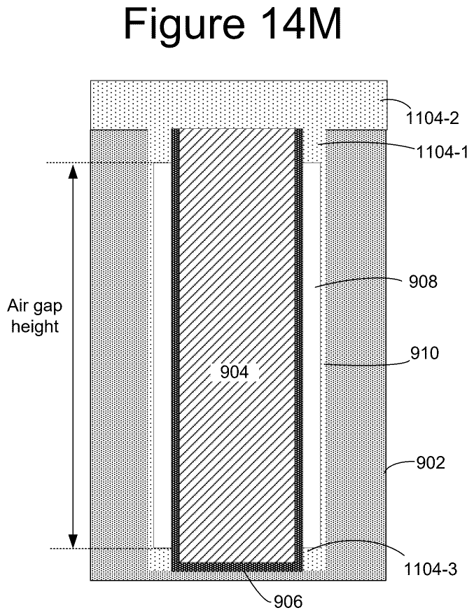

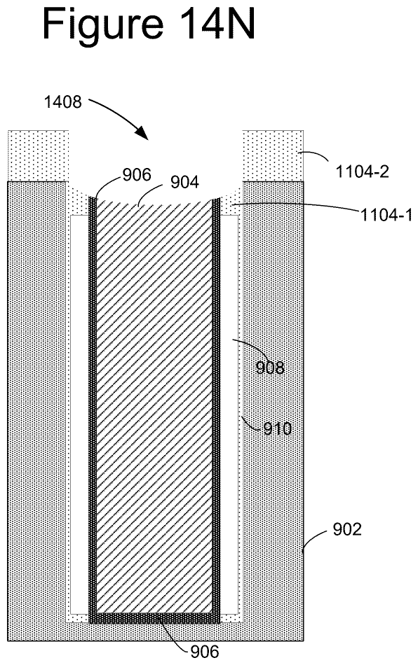

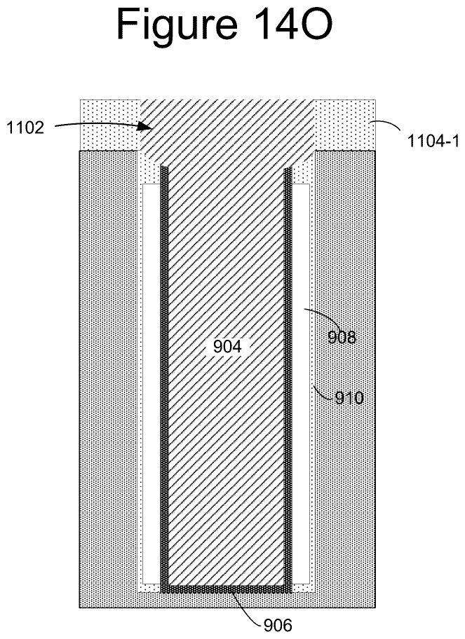

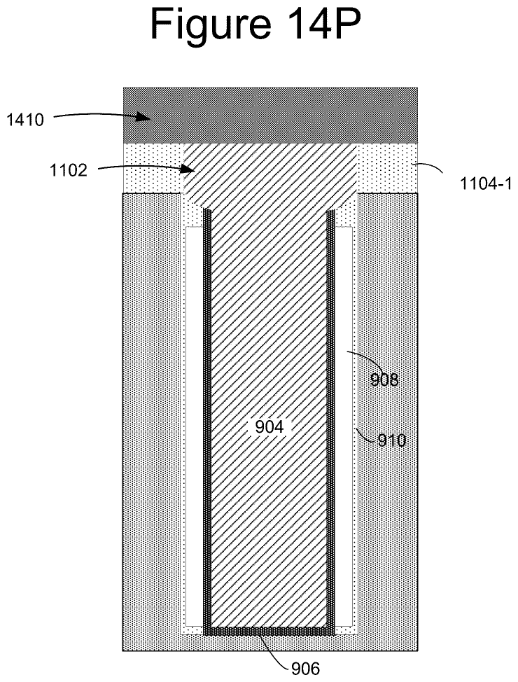

FIG. 13 is a flowchart of one embodiment of a process 1300 of fabricating a DTC/TSV in a substrate. The substrate may be a crystalline silicon substrate. The DTC may extend entirely through the crystalline silicon substrate in which case it is referred to as a TSV. However, the DTC is not required to extend entirely though the crystalline silicon substrate. In a stack 600 such as in FIG. 6B, most of the DTCs for the control dies will have a TSV. The process 1300 may be used to form a structure such as one of the DTCs 832 as depicted in FIGS. 11A and 11B. The process 1300 will be described with reference to FIGS. 14A-14P. FIGS. 14A-14P will use reference numbers used in FIGS. 11A and 11B. Step 1302 includes etching the substrate to create an opening for the DTC/TSV. FIGS. 14A and 14B depict results after an embodiment of step 1302. FIG. 14A depicts a cross-sectional showing the opening 1402 in the substrate 902. FIG. 14B shows the opening 1402 in the substrate 902 from the perspective of the arrows in line 14B-14B in FIG. 14A. As noted the substrate 902 may be a crystalline silicon substrate.

Step 1304 includes thermal oxidation of sidewalls of the opening 1402. The thermal oxidation may be used to form the silicon dioxide 910 layer on a silicon substate 902. FIGS. 14C and 14D depict results after an embodiment of step 1304. FIG. 14C depicts a cross-sectional showing the silicon dioxide 910 on the surface the silicon substrate 902 in the opening 1402. FIG. 14D shows the silicon dioxide 910 on the surface the silicon substrate 902 from the perspective of the arrows in line 14D-14D in FIG. 14C.

Step 1306 includes depositing a sacrificial material over the silicon dioxide 910 layer. In an embodiment, the sacrificial material is silicon nitride (SiN). However, other sacrificial layers such as amorphous silicon, amorphous carbon, amorphous silicon-oxide-carbon composites, etc., may also be used. The sacrificial material will be removed later in the process 1300 to leave an opening for the air gap. Step 1308 includes performing a reactive ion etch (RIE) to remove a bottom portion of the sacrificial material. FIGS. 14E and 14F depict results after an embodiment of step 1308. FIG. 14E depicts a cross-sectional showing sacrificial material 1404 on the surface the silicon dioxide 910 layer on the sidewalls the opening 1402 in the substrate 902. The RIE has been used to etch through sacrificial material 1404 and the silicon dioxide 910 at the bottom 1405 of the opening 1402. Thus, the silicon substrate 902 is now exposed at the bottom 1405 of the opening 1402. FIG. 14F shows the sacrificial material 1404 on the surface the silicon dioxide 910 from the perspective of the arrows in line 14F-14F in FIG. 14E.

Step 1310 includes depositing a barrier material in the opening over the sacrificial material 1404 and over the silicon substate 902 at the bottom of the opening. In one embodiment, the barrier material is titanium nitride. FIGS. 14G and 14H depict results after an embodiment of step 1310. FIG. 14G depicts a cross-sectional view showing the barrier material 906 on the surface the sacrificial material 1404. The barrier material 906 is also on the surface the silicon substrate 902 at the bottom of the opening. FIG. 14H shows the barrier material 906 on the surface the sacrificial material 1404 from the perspective of the arrows in line 14H-14H in FIG. 14G.

Step 1312 includes forming metal for the conductive column of the DTC/TSV. The metal is formed on the barrier material. In one embodiment, The barrier material is lined with a seed layer, and the seed layer may be plated with a metal such as copper, although other suitable materials such as aluminum, tin, nickel, gold, and alloys or combinations thereof may be used. FIGS. 14I and 14J depict results after an embodiment of step 1312. FIG. 14I depicts a cross-sectional view showing the metal for the conductive column 904 on the surface the barrier material 906. FIG. 14J shows the metal for the conductive column 904 on the surface the barrier material 906 from the perspective of the arrows in line 14J-14J in FIG. 14I.

Step 1314 includes etching away the sacrificial material. Etching away the sacrificial material reveals an opening for the air gap. FIGS. 14K and 14L depict results after an embodiment of step 1314. FIG. 14K depicts a cross-sectional view showing the opening for the air gap 908. FIG. 14L shows the opening for the air gap 908 from the perspective of the arrows in line 14L-14L in FIG. 14K.

Step 1316 includes depositing a cap layer at the top of the opening in the substate 902 leaving the air gap 908. The cap layer may be formed from, for example, SiO₂ or SiCN. Step 1316 may include non-conformal deposition of the cap layer material. In some embodiments, the cap layer is deposited by chemical vapor deposition or atomic layer deposition techniques or other techniques. FIG. 14M depicts results after an embodiment of step 1316. FIG. 14M depicts a cross-sectional view showing the cap layer 1104. The cap layer may have a cap portion 1104-1 within the opening and a cap portion 1104-2 above the surface of the substate 902 and above the conductive column 904. The air gap 908 remains after the cap layer 1104 has been formed. In an embodiment, the air gap 908 has a high aspect ratio. As an example, the height of the air gap 908 could be more than one micron. As one non-limiting example, the height of the air gap 908 could be about 20 microns. However, air gaps 908 with heights greater or smaller than 20 microns may be formed. The formation of the cap portion could also result formation of a bottom cap 1104-3.

Step 1318 includes forming a recess in the cap layer 1104 to reveal the metal of the conductive column 904. Step 1318 may include performing an RIE to etch a portion of the cap layer 1104. FIG. 14N depicts results after an embodiment of step 1318. FIG. 14N depicts a cross-sectional view showing a recess 1408 in the cap layer 1104. The recess 1408 exposes the metal to the top of the conductive column 904. The recess 1408 may also expose some of the barrier material 906. The recess 1408 may cut away some of the cap portion 1104-1 that is in the opening. However, at least some of the cap portion 1104-1 remains in the opening such that the air gap 908 still has the cap portion 1104-1 above it.

Step 1320 includes depositing metal for a bonding pad in the recess 1408. FIG. 14O depicts results after an embodiment of step 1320. FIG. 14O depicts a cross-sectional view showing a bonding pad 1102 in what was the recess 1408 in the cap layer 1104. The bonding pad 1102 is in direct contact with the metal of the conductive column 904.

Step 1322 includes depositing a bonding pad cap layer over the bonding pad. FIG. 14P depicts results after an embodiment of step 1322. FIG. 14P depicts a cross-sectional view showing a bonding pad cap layer 1410 over the bonding pad 1102. The bonding pad cap layer 1410 may also cover the cap portion 1104-1.

In view of the foregoing, an embodiment includes an apparatus comprising a stack of dies comprising control circuitry and non-volatile memory cells. The control circuitry is configured to apply signals to the non-volatile memory cells to control the non-volatile memory cells. The apparatus comprises a plurality of deep trench contacts that extend through the stack of dies and are coupled to the control circuitry to permit off die communication with the control circuitry. Each deep trench contact comprises an electrical pathway and a low permittivity dielectric surrounding at least a portion of the electrical pathway.

In an embodiment of the apparatus, the stack of dies comprise a first die having a first semiconductor substrate. A portion of the control circuitry resides in the first semiconductor substrate. The plurality of deep trench contacts comprise through silicon vias (TSVs) that extend through the first semiconductor substrate.

In an embodiment of the apparatus, the stack of dies comprise a first die having a first semiconductor substrate and a second die having a second semiconductor substrate. The plurality of deep trench contacts comprise a first plurality of through silicon vias (TSVs) that extend through the first semiconductor substrate and a second plurality of through silicon vias (TSVs) that extend through the second semiconductor substrate. One or more TSV of the first plurality of TSVs is bonded to a corresponding TSV of the second plurality of TSVs.

In an embodiment, the apparatus further comprises a memory controller connected to the stack of dies. The memory controller includes a communication interface connected to the deep trench contacts. The communication interface is configured to communicate signals with the control circuitry in the stack of dies over the electrical pathways in the deep trench contacts.

In an embodiment, the electrical pathways comprise data input/output (I/O) lines.

In an embodiment, the low permittivity dielectric comprises an air gap.

In an embodiment, an aspect ratio of the air gap is at least 20.

In an embodiment, the electrical pathways comprise cylindrical conductive columns and the low permittivity dielectric surrounds the cylindrical conductive columns.

In an embodiment, the low permittivity dielectric comprises a solid dielectric material having a lower relative permittivity than relative permittivity of silicon dioxide (SiO₂).

In an embodiment, the low permittivity dielectric comprises a dielectric material having a relative permittivity between 1.1 and 3.8.

In an embodiment, the low permittivity dielectric comprises a dielectric material having a relative permittivity between 1.5 and 3.0.

An embodiment includes a method comprising forming first through silicon vias (TSVs) through a first crystalline semiconductor substrate of a first semiconductor die, including forming for each first TSV an air gap surrounding a conductive column. The method comprises forming first memory cell control circuitry on the first crystalline semiconductor substrate. The method comprises forming second through silicon vias (TSVs) through a second crystalline semiconductor substrate of a second semiconductor die, including forming for each first TSV an air gap surrounding a conductive column. The method comprises forming second memory cell control circuitry on the second crystalline semiconductor substrate. The method comprises bonding the conductive columns of the first TSVs to corresponding ones of the conductive columns of the second TSVs.

An embodiment includes a non-volatile memory system, comprising a plurality of mirror dies in a stack. Each mirror die comprises first NAND memory cells and second NAND memory cells. Each mirror die comprises a first die having a first crystalline silicon substrate and a second die having a second crystalline silicon substrate. The first crystalline silicon substrate has first control circuitry configured to control the first NAND memory cells. The second crystalline silicon substrate has second control circuitry configured to control the second NAND memory cells. The non-volatile memory system has a plurality of through silicon vias (TSVs) that extend through the first crystalline silicon substrate and the second crystalline silicon substrate. Each TSV has a conductive column and a low permittivity dielectric surrounding the conductive column.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects. For example, a “set of reference voltages” may contain one or more reference voltages.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus, comprising:
a stack of dies comprising control circuitry and non-volatile memory cells, wherein the control circuitry is configured to apply signals to the non-volatile memory cells to control the non-volatile memory cells; and
a plurality of deep trench contacts that extend through the stack of dies and are coupled to the control circuitry to permit off-die communication with the control circuitry, each deep trench contact comprising an electrical pathway and a low permittivity dielectric surrounding at least a portion of the electrical pathway.

2. The apparatus of claim 1, wherein:
the stack of dies comprise a first die having a first semiconductor substrate;
a portion of the control circuitry resides in the first semiconductor substrate; and
the plurality of deep trench contacts comprise through silicon vias (TSVs) that extend through the first semiconductor substrate.

3. The apparatus of claim 1, wherein the stack of dies comprise:
a first die having a first semiconductor substrate; and
a second die having a second semiconductor substrate, the plurality of deep trench contacts comprise:
a first plurality of through silicon vias (TSVs) that extend through the first semiconductor substrate; and
a second plurality of through silicon vias (TSVs) that extend through the second semiconductor substrate, one or more TSV of the first plurality of TSVs is bonded to a corresponding TSV of the second plurality of TSVs.

4. The apparatus of claim 1, further comprising a memory controller connected to the stack of dies, wherein the memory controller includes a communication interface connected to the deep trench contacts, wherein the communication interface is configured to communicate signals with the control circuitry in the stack of dies over the electrical pathways in the deep trench contacts.

5. The apparatus of claim 4, wherein the electrical pathways comprise data input/output (I/O) lines.

6. The apparatus of claim 1, wherein the low permittivity dielectric comprises an air gap.

7. The apparatus of claim 6, wherein an aspect ratio of the air gap is at least 20.

8. The apparatus of claim 1, wherein:
the electrical pathways comprise cylindrical conductive columns; and
the low permittivity dielectric surrounds the cylindrical conductive columns.

9. The apparatus of claim 1, wherein the low permittivity dielectric comprises a solid dielectric material having a lower relative permittivity than relative permittivity of silicon dioxide (SiO₂).

10. The apparatus of claim 1, wherein the low permittivity dielectric comprises a dielectric material having a relative permittivity between 1.1 and 3.8.

11. The apparatus of claim 1, wherein the low permittivity dielectric comprises a dielectric material having a relative permittivity between 1.5 and 3.0.

12. A method comprising:
forming first through silicon vias (TSVs) through a first crystalline semiconductor substrate of a first semiconductor die, including forming for each first TSV an air gap surrounding a conductive column;
forming first memory cell control circuitry on the first crystalline semiconductor substrate;
forming second through silicon vias (TSVs) through a second crystalline semiconductor substrate of a second semiconductor die, including forming for each first TSV an air gap surrounding a conductive column;
forming second memory cell control circuitry on the second crystalline semiconductor substrate; and
bonding the conductive columns of the first TSVs to corresponding ones of the conductive columns of the second TSVs.

13. The method of claim 12, wherein forming each TSV of the first TSVs comprises:
depositing a sacrificial material in an opening in the first crystalline semiconductor substrate;
forming the conductive column inside of the sacrificial material; and
removing the sacrificial material to reveal the air gap surrounding the conductive column.

14. The method of claim 13, further comprising:
forming a cap layer to enclose the air gap.

15. A non-volatile memory system, comprising:
a plurality of mirror dies in a stack, each mirror die comprising first NAND memory cells and second NAND memory cells, each mirror die comprising a first die having a first crystalline silicon substrate and a second die having a second crystalline silicon substrate, the first crystalline silicon substrate having first control circuitry configured to control the first NAND memory cells, the second crystalline silicon substrate having second control circuitry configured to control the second NAND memory cells; and
a plurality of through silicon vias (TSVs) that extend through the first crystalline silicon substrate and the second crystalline silicon substrate, each TSV having a conductive column and a low permittivity dielectric surrounding the conductive column.

16. The non-volatile memory system of claim 15, wherein the low permittivity dielectric comprises an air gap.

17. The non-volatile memory system of claim 15, wherein the low permittivity dielectric comprises a material having a dielectric constant between 1.1 to 3.8.

18. The non-volatile memory system of claim 15, further comprising a memory controller die connected to the stack of mirror dies, the memory controller die including a communication interface coupled to the TSVs, the communication interface configured to transmit signals over the TSVs to access the first NAND memory cells and the second NAND memory cells in the plurality of mirror dies.

19. The non-volatile memory system of claim 15, wherein the plurality of TSVs comprise data input/output (I/O) lines.

20. The non-volatile memory system of claim 19, further comprising a memory controller connected to the data I/O lines, wherein the memory controller is configured to:
send, over the data I/O lines, data to be stored in the first NAND memory cells and the second NAND memory cells in the plurality of mirror dies; and
receive, over the data I/O lines, data read from the first NAND memory cells and the second NAND memory cells in the plurality of mirror dies.
